(19) United States
(12) Patent Application Publication
(10) Pub. No.: US 2009/0181500 A1
(43) Pub. Date: Jul. 16, 2009

(54) Fabrication of Compact Semiconductor Packages

(76) Inventors: Jochen Kuhmann, Berlin (DE); Andreas A. Hase, Berlin (DE)

Correspondence Address: FISH & RICHARDSON P.C., P.O. BOX 1022, MINNEAPOLIS, MN, 55440-1022, US

(21) Appl. No.: 12/014,443

(22) Filed: Jan. 15, 2008

(51) Int. Cl. H01L 21/58

(52) U.S. Cl. 438/121; 257/E21.505

(57) ABSTRACT

A wafer-level method of fabricating a chip-to-wafer or wafer-to-wafer semiconductor packages includes etching a cavity into a first semiconductor wafer and etching vias in a bottom of the cavity. The cavity and sidewalls of the vias are selectively metallized. The cavity can be used to house either an electrical circuit component or to contain a device die. A second semiconductor wafer is placed over the cavity-side of the first semiconductor and is sealed to the first semiconductor wafer. A backside of the first semiconductor wafer is thinned to expose metallization in the vias and metal is deposited on the backside to form circuit routing paths.

### TECHNICAL FIELD

This disclosure relates to semiconductor packaging.

### BACKGROUND

As features and capabilities of consumer electronic products grows, there is an increasing need to fit more circuit elements (e.g., electrical circuit components, integrated circuit dies, microelectromechanical system dies, optoelectromechanical systems, or other such devices) in an ever decreasing space. Typically, the dimensions of a printed circuit board (PCB) and circuit elements are dictated by the size of the consumer electronic product and the available space within the product. Often, the height of an assembled PCB (e.g., the circuit elements mounted on both sides of the PCB) is limited to be only one millimeter (mm) whereas the typical height of the assembled PCB is 1.5 mm (a typical height of a PCB is 500 microns (μm) and a typical height of circuit elements is 500 μm). Therefore, either the size of the assembled PCB must be reduced or features and capabilities must be reduced to fit the assembled PCB into the limited available space.

### SUMMARY

Techniques are disclosed for fabricating a compact semiconductor package for housing circuit elements. The packages may be fabricated in a wafer-level batch process. In one implementation, the wafer-level method of fabricating a semiconductor package is implemented to fabricate a chip-to-wafer package. The method includes etching a cavity into a first semiconductor wafer and etching vias in a bottom of the cavity. The cavity and sidewalls of the vias are selectively metallized and an electrical circuit component is mounted in the cavity. A second semiconductor wafer is placed over the cavity-side of the first semiconductor and is sealed to the first semiconductor wafer. A backside of the first semiconductor wafer is thinned to expose metallization in the vias and metal is deposited on the backside of the first semiconductor package to form circuit routing paths.

In a different implementation, the method of fabricating a semiconductor package can be implemented to fabricate a wafer-to-wafer package. The method includes etching a cavity into a first semiconductor wafer and etching vias in a bottom of the cavity. The cavity and sidewalls of the vias are selectively metallized. A second semiconductor wafer, containing a device die, is placed over the cavity-side of the first semiconductor such that the device die is contained in the cavity. The second semiconductor wafer is then sealed to the first semiconductor wafer. A backside of the first semiconductor wafer is thinned to expose metallization in the vias and metal is deposited on the backside of the first semiconductor package to form circuit routing paths.

An advantage of some implementations is to make particularly thin semiconductor packages.

The details of one or more implementations of the invention are set forth in the accompanying drawings and the description below.

Other features and advantages will be apparent from the description and drawings, and from the claims.

### DESCRIPTION OF DRAWINGS

FIG. 1 is a cross-section of a substantially flat chip-to-wafer semiconductor package.

FIG. 2 is a flowchart illustrating an example of a process to form a chip-to-wafer semiconductor package.

FIG. 3 is an illustration of a semiconductor wafer.

FIG. 4 is an illustration of a base with a base cavity.

FIG. 5 is an illustration of the base with vias.

FIG. 6 is an illustration of the base after a metallization process.

FIG. 7 is an illustration of the a discrete component mounted on the base.

FIG. 8 is an illustration of a lid sealed to the base.

FIG. 9 is an illustration of the surface-mount-device side of the base.

FIG. 10 is an illustration of the surface-mount-device side of the base with electric circuit routing and/or circuit connections.

FIG. 11 is an illustration of the surface-mount-device side of the base after pad formation.

FIG. 12 is cross-section of a substantially flat wafer-to-wafer semiconductor package.

FIG. 13 is a flowchart illustrating an example of a process to form a wafer-to-wafer semiconductor package.

FIG. 14 is an illustration of a base with a base cavity.

FIG. 15 is an illustration of the base with vias.

FIG. 16 is an illustration of the base after a metallization process.

FIG. 17 is an illustration of a lid sealed to the base.

FIG. 18 is an illustration of the surface-mount-device side of the base.

FIG. 19 is an illustration of the surface-mount-device side of the base with the electric circuit routing and/or circuit connections.

FIG. 20 is an illustration of the surface-mount-device side of the base after pad formation.

### DETAILED DESCRIPTION

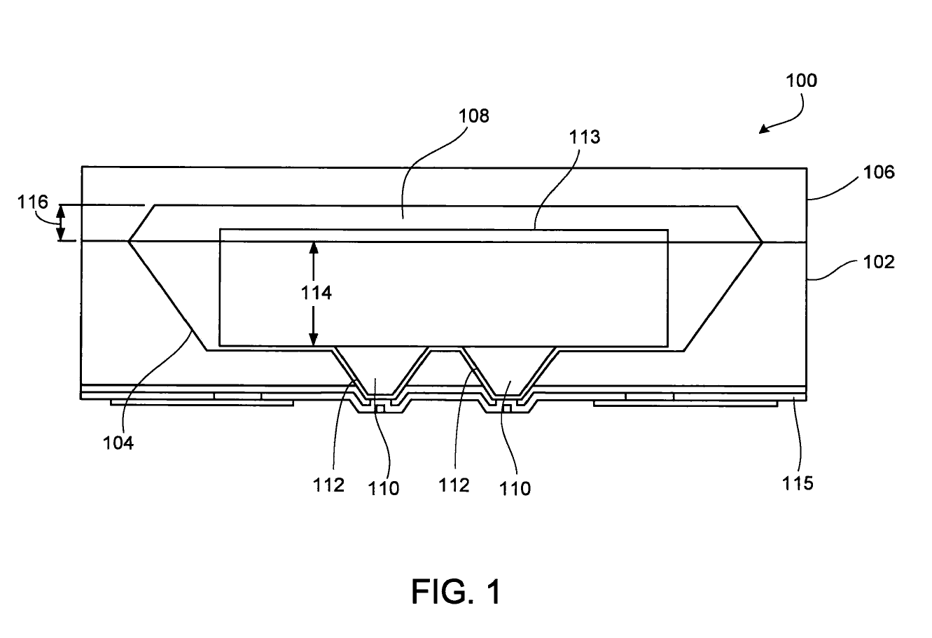

FIG. 1 illustrates an example of a substantially flat chip-to-wafer semiconductor package 100. The chip-to-wafer semiconductor package 100 includes a base 102, a base cavity 104, a lid 106, a lid cavity 108, one or more vias 110 with feed-through metallization 112, and an electrical circuit component 113. In the illustrated example, the base 102 is formed from a silicon or other semiconductor wafer. The physical dimensions of the base 102 may vary depending on the application or the intended use of the chip-to-wafer semiconductor package 100. An example base 102 can have a thickness of 245 μm, a width of 1100 μm and a length of 1400 μm. The base 102 contains a base cavity 104 having a depth 114. The depth 114 of the base cavity can be increased or decreased to accommodate the height of different electrical circuit components such as discrete electrical components (e.g., resistors, transistors, integrated circuits, chips, or capacitors). For example, if an electrical circuit component 113 with a height of 135 μm is placed in the base cavity 104, the depth 114 of the base cavity may be slightly more than 135 μm. The depth 114 of the base cavity also can be adjusted based on the depth 116 of the lid cavity, which is described below.

The base 102 contains one or more vias 110 with feed-through metallization 112 that extends from the bottom of the base cavity 104 to the surface-mount-device (SMD) side 115 of the base (i.e., the side of the base 102 that is to be mounted to the PCB). The feed-through metallization 112 in each of the vias 110 protrudes from the SMD side 115 of the base 102 and is used to form electrical interconnections with the electrical circuit components 113 placed in the base cavity 104. The number of vias 110 is dependant on the electrical circuit component 113 that is to be placed in the base cavity 104 and/or the application.

The lid 106 is formed from a silicon, a glass, or other material wafer. The lid 106 contains a lid cavity 108 with a depth 116. The depth 116 of the lid cavity can be increased or decreased to accommodate the height of the electrical circuit component 113. The depth 116 of the lid cavity also can be adjusted based on the depth 114 of the base cavity. Referring to the example above, if an electrical circuit component 113 has a height of 135 μm, the depth 114 of the base cavity may be a little more than 125 μm and the depth 116 of the lid cavity may be a little more than 10 μm. In addition, the depth 116 of the lid cavity and the depth 114 of the base cavity can be adjusted so they are equal to slightly more than half of the height of the electrical circuit component 113. In the foregoing example, the depth 116 of the lid cavity and the depth 114 of the base cavity would be about 67.5 μm each.

The lid 106 is sealed to the base 102. Example methods to seal the lid 106 to the base 102 are a gold-tin (AuSn) hermetic sealing process or an adhesive bonding process. The lid 106 is positioned on the base 102 so the lid cavity 116 is aligned with the base cavity 104 and the electrical circuit component 113 is housed within the area defined by the lid cavity 116 and the base cavity 104.

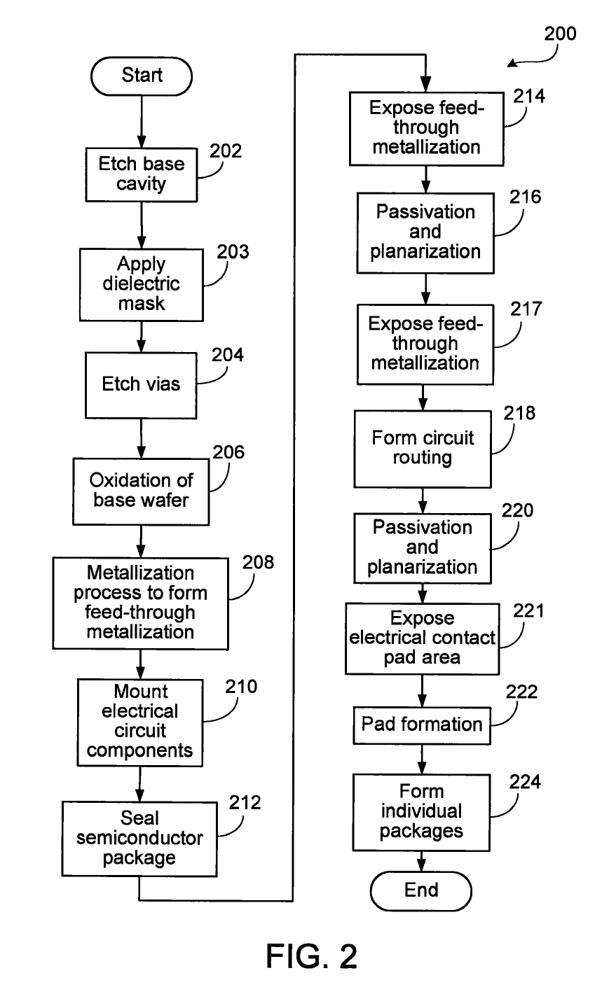

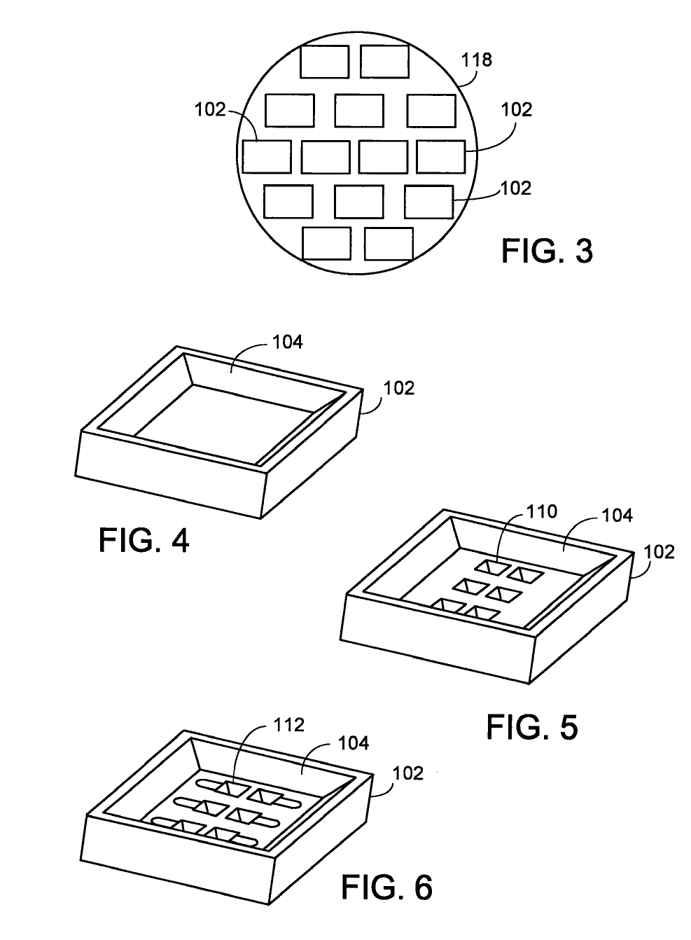

FIG. 2 is a flowchart illustrating a wafer-level process 200 to form the chip-to-wafer semiconductor package 100. The process 200 is typically performed on a silicon or other semiconductor wafer to fabricate multiple bases 102 or lids 106. An example semiconductor wafer 118 with areas defining multiple bases 102 is shown in FIG. 3. However, for ease of discussion and illustration, the individual steps of process 200 will be described as being performed with respect to a single base 102 from the semiconductor wafer 118. In addition, FIGS. 4-11 illustrate the process 200 as performed on a single base 102 or lid 106. A person of ordinary skill in the art will recognize that each step described below is performed for each base 102 and/or lid 106.

The process 200 begins with a silicon or other semiconductor wafer of a thickness, for example, in the range of 450-560 μm. The area defining the base 102 is etched to form a base cavity 104 (block 202). Various types of wet etching processes may be used to form the base cavity 104. For example, the base cavity 104 can be etched using a potassium hydroxide (KOH) etching process or a tetramethyl ammonium hydroxide (TMAH) etching process. FIG. 4 illustrates an example base 102 after the base cavity 104 has been etched into it.

After the base cavity 104 is etched, a dielectric mask, such as silicon dioxide (SiO₂) or silicon nitride (SiₓN_{y}), is applied to the base 102 and the base cavity 104 (block 203). The vias 110 then are etched into the bottom of the base cavity 104 (block 204). The vias 110 can be etched using a wet etching technique such as KOH etching or TMAH etching. Alternatively, the vias 110 can be etched using a dry etching technique. The vias 110 can be etched, for example, to a depth of 20-60 μm. However, the vias 110 are etched so they do not penetrate the bottom of the base 102 (i.e., the vias 110 remain buried). FIG. 5 provides an illustration of the base 102 after the vias 110 are etched.

The base 102 undergoes an oxidation process, and a thin layer of a dielectric, such as SiO₂, is deposited on the surface of the base 102, the base cavity 104, and the vias 110 (block 206). Although the illustrated process 200 includes depositing a thin layer of SiO₂, other types of dielectric may be applied.

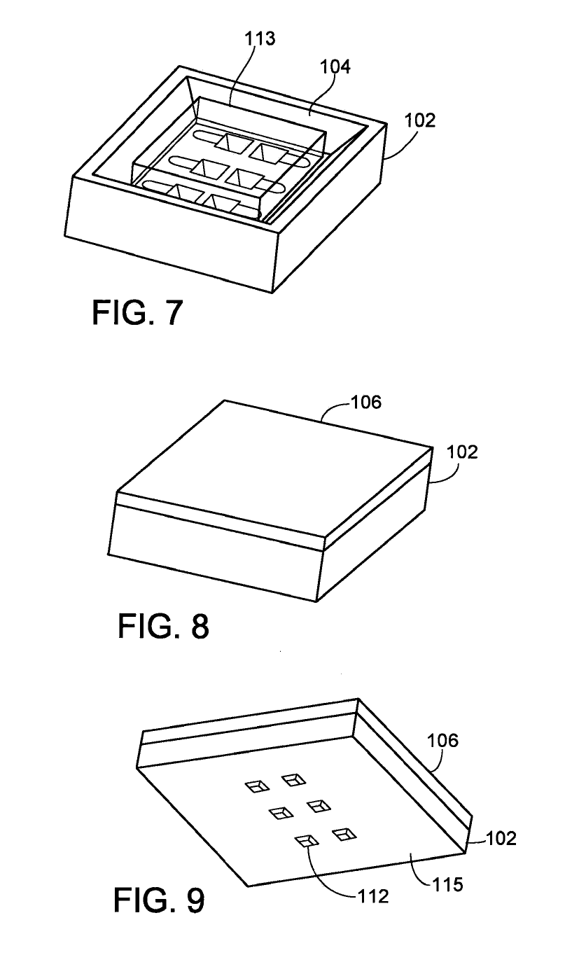

The base cavity 104 and the vias 110 undergo a metallization process that forms the feed-through metallization 112 (block 208). Conductive metal, such as gold (Au) or some other conductive metal, is deposited on predetermined portions of the surface of the base cavity 104 and the vias 110. The feed-through metallization 112 is formed by the deposition of the conductive metal in the vias 110. FIG. 6 is an illustration of the base cavity 104 and the feed-through metallization 112 after the metallization process is completed. An electrical circuit component 113 then is mounted in the base cavity 104 (block 210). FIG. 7 provides an illustration of the base 102 after the electrical circuit component 113 is mounted into the base cavity 104. A mounting technique using flip chip technology is preferred over a wire bonding process because the wire bonding process requires more space within the base cavity 104.

After the electrical circuit component 113 is mounted, the lid 106 is positioned on the base 102 such that the lid cavity 108 is aligned with the base cavity 104 and is sealed to the base 102 (block 212). The lid 106 can be sealed to the base 102 with AuSn hermetic sealing process, adhesive bonding or some other type of sealing process. FIG. 8 is an illustration of the semiconductor package 100 with the lid 106 sealed to the base 102.

After the lid 106 is sealed to the base 102, the SMD side 115 is processed to expose the feed-through metallization 112 in the vias 110 (block 214). A mechanical grinding technique is used to reduce the thickness of the base 102 from the SMD side 115 and to make a particularly thin package. The chip-to-wafer semiconductor package 100 is supported by the lid 106 for mechanical stability during the grinding process. The SMD side 115 is thinned until there is approximately 10-20 μm separating the SMD side 115 and the vias 110. The SMD side 115 then is dry etched to expose the feed-through metallization 112. For example, the SMD side 115 can be dry etched using a reactive ion etching (RIE) process. As the base 102 is made from silicon and the vias 110 are metallized and protected by a layer of dielectric material, such as SiO₂ or SiₓN^{y}, the material of the base 102 is removed at a faster rate than the dielectric coating of the vias 110. As shown in FIG. 9, this difference in etching rate results in the feed-through metallization 112 being exposed and protruding slightly beyond the SMD side 115 of the base. Other techniques to expose the feed-through metallization 112 may be used.

Next, the surface of the SMD side 115 undergoes a benzocyclobutene (BCB) passivation and planarization process (block 216). Although the illustrated process 200 describes using a BCB passivation and planarization process, other types of polymers having similar properties to BCB may be used. The BCB passivation and planarization process passivates and planarizes the SMD side 115. As a result of the BCB passivation and planarization process, the feed-through metallization 112 is buried by the BCB layer The portions of the BCB layer covering the vias 110 and feed-through metallization 112 then are removed (i.e., the feed-through metallization 112 is exposed) using a photolithographic technique followed by etching (block 217).

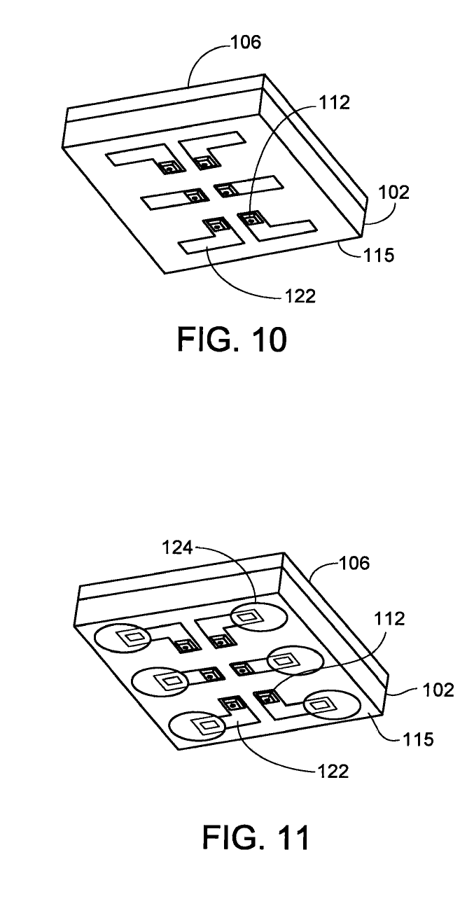

After the vias 110 and feed-through metallization 112 are exposed, a metallization process is performed to create the circuit routing 122 on the SMD side 115 (block 218). The metallization process can be an electroplating process using a photoresist mold, or a physical vapor deposition (PVD) process or any other type of process. The metallization process forms a layer of a conductive metal or alloy on the surface of the SMD side 115. The metal can be, but is not limited to, titanium-gold (TiAu) or titanium-copper (TiCu). If a PVD process is used, the metal is etched to form the circuit routing 122. FIG. 10 illustrates the SMD side 115 of the base after the circuit routing 122 is formed.

The SMD side 115 of the base 102 then undergoes a second BCB passivation process to planarize and insulate the circuit routing 122 (block 220). As a result of the second BCB passivation process, the vias 110, the feed-through metallization 112 and the circuit routing 122 are buried by the BCB layer. Using techniques similar to the techniques described with respect to block 217, the areas of the SMD side 115 where the electrical contact pads 124 will be formed (i.e., the electrical contact pad areas) are exposed with a photolithographic technique and an etching process (block 221). The electrical contact pads 124 are then formed on the SMD side 115 of the base 102 (block 222). The electrical contact pads 124 are formed by an electroplating process or a PVD process and are formed on predetermined areas including areas on the circuit routing 122. FIG. 11 provides an illustration of the SMD side 115 of the base after the electrical contact pads 124 are formed.

After the electrical contact pads 124 are formed, each individual chip-to-wafer semiconductor package 100 is formed (block 224). The individual chip-to-wafer semiconductor package 100 can be formed by a dicing process. Other methods may be used to form individual semiconductor packages 100 from the semiconductor wafer.

In one implementation, the top of the lid 106 (i.e., the externally-facing surface of the lid 106) can be thinned after the electrical contact pads 124 are formed to make the semiconductor package 100 particularly thin. The top of the lid 106 can be thinned using a mechanical grinding technique or an etching process can be used to thin the lid 106. Alternatively, the top of the lid 106 may be thinned at any step after the lid 106 and the base 102 are sealed (i.e., at any step after block 212). For example, the top of the lid 106 can be thinned after the SMD side 115 is thinned in block 214.

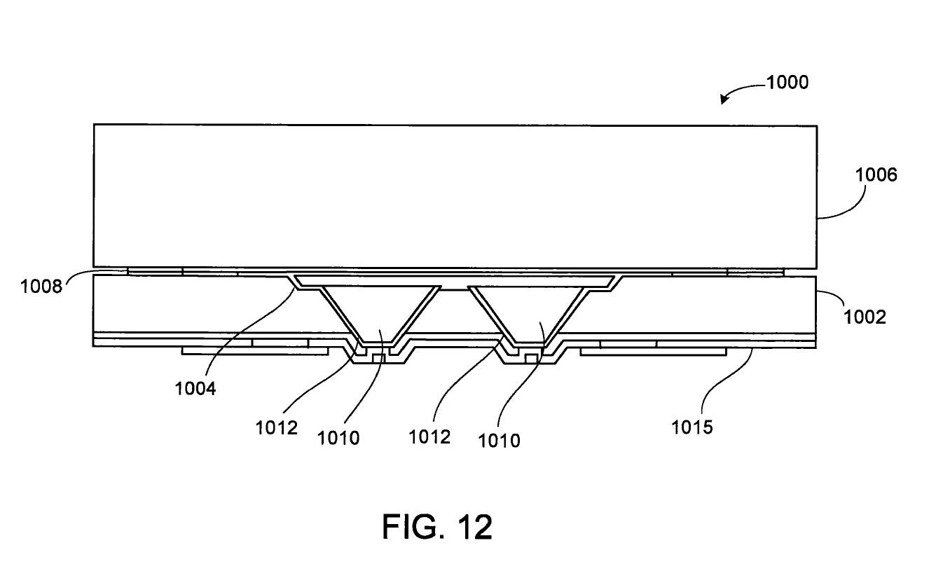

FIG. 12 illustrates an example of a substantially flat wafer-to-wafer semiconductor package 1000. The wafer-to-wafer semiconductor package 1000 comprises a base 1002, a base cavity 1004, a lid 1006, a sealing ring 1008, one or more vias 1010 with feed-through metallization 1012. The base 1002 is formed from a silicon or other semiconductor wafer. The physical dimensions of the base 1002 may vary depending on the application or the size of a device die (e.g., a microelectromechanical system (MEMS) die, an optoelectromechanical system or an integrated circuit die) to be housed in the base 1002. An example base 1002 may have a thickness of 100 μm, a width of 1000 μm and a length of 1290 g/m. The base 1002 contains a base cavity 1004. The depth of the base cavity 1004 can change to accommodate the thickness of the device die. An example depth of the base cavity 1004 is 20 μm. However, the base cavity 1004 typically is not as deep as the base cavity 104 used in the chip-to-wafer semiconductor package 100.

The base 1002 contains one or more vias 1010 with feed-through metallization 1012 that extends from the bottom of the base cavity 1004 to the SMD side 1015 of the base 1002. The feed-through metallization 1012 in each via 1010 protrudes from the SMD side 1015 of the base 1002 and is used to provide electrical interconnections with the device die. The number of vias 1010 is dependent on the device die and/or the application of the semiconductor package 1000. The base 1002 also can include the sealing ring 1008. The sealing ring 1008 provides a seal so the device die is hermetically housed within the wafer-to-wafer semiconductor package 1000.

The lid 1006 is formed from a silicon or other semiconductor wafer and contains a device die. The device die can be formed on the lid 1006 (i.e., the lid 1006 is the device die). The device die can be any type of circuitry such as MEMS or an electrical circuit component. In addition, the lid 1006 can have electrical contact pads. In one implementation, the lid 1006 can act as a filter and can filter signals that are transmitted from the wafer-to-wafer semiconductor package 1000 or the device die. For example, the lid 1006 can act as a band-pass filter and filter signals from the wafer-to-wafer semiconductor package 1000 that are outside a predetermined frequency range.

The lid 1006 is positioned on the base 1002 and then sealed to the base 1002. The lid 1006 may be sealed, for example, using a AuSn hermetic sealing process or an adhesive bonding process. The lid 1006 is positioned on the base 1002 so that the lid 1006 and base 1002 are aligned and the device die is contained within the base cavity 1004.

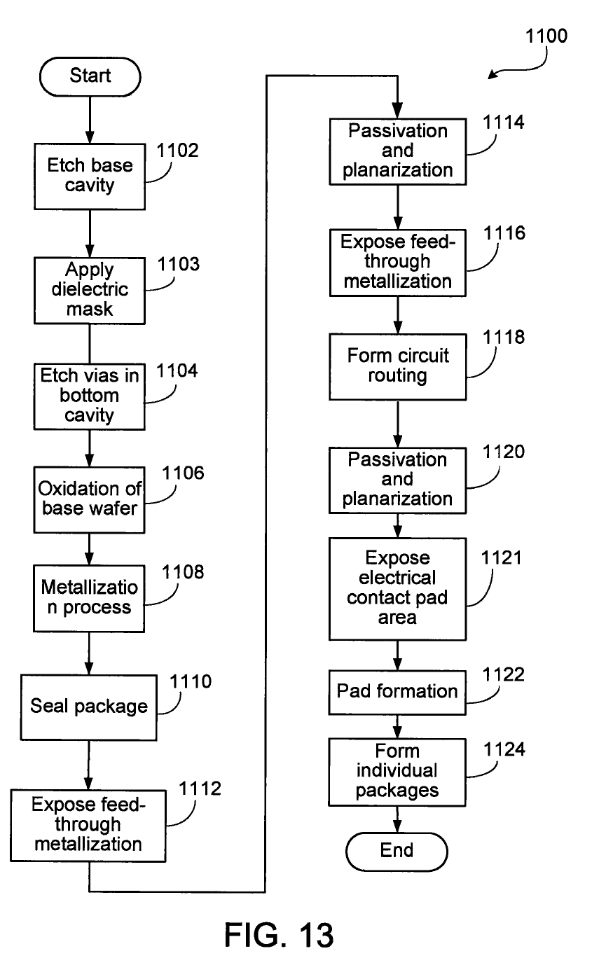

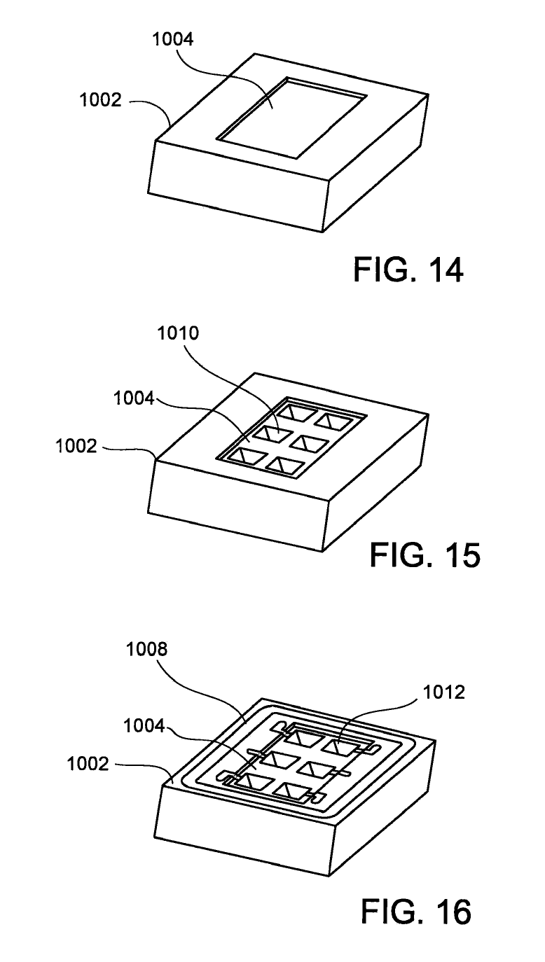

FIG. 13 is a flowchart illustrating a wafer level process 1100 to form the wafer-to-wafer semiconductor package 1000. The process 1100 is typically performed on a silicon or other semiconductor wafer to fabricate multiple bases 1002 or lids 1006, as described above in connection with process 200. However, for ease of discussion and illustration, the individual steps of process 1100 will be described as being performed with respect to a single base 1002 or lid 1006. In addition, FIGS. 14-20 illustrate the process 1100 as performed on a single base 1002 or lid 1006. A person of ordinary skill in the art will recognize that each step described below is performed for each base 1002 or lid 1006.

The process 1100 begins with a base 1002 that may be silicon or other type of semiconductor and have a thickness, for example, in the range of 450-560 μm. The base 1002 is etched to form a base cavity 1004 (block 1102). Any type of wet etching process may be used to form the base cavity 1004. For example, the base cavity 1004 may be etched using a KOH etching process or a TMAH etching process. The base cavity 1004 need not be as deep as the base cavity 104 in the flat chip-to-wafer semiconductor package 100 because the base cavity 1004 does not need to provide room for an electrical circuit component 113. Instead, the base cavity 1004 is etched to a depth so that a device die can be contained in the base cavity 1004. The device die typically has a thickness of 450-560 μm. FIG. 14 is an illustration of a base 1002 after the base cavity 1004 is etched into it.

After the base cavity 1004 is etched, a dielectric mask, such as SiO₂ or SiN, is applied to the base 1002 and the base cavity 1004 (block 1103). The vias 1010 are then etched into the bottom of the base cavity 1004 (block 1104). The vias 1010 can be etched using a wet etching technique such as KOH etching or TMAH etching. Alternatively, the vias 1010 can be etched using a dry etching technique. The vias 1010 can be etched, for example, to a depth of 20-60 μm, but should not penetrate the bottom of the base 1002 (i.e., the vias 1010 remain buried). FIG. 15 is an illustration of the base cavity 1004 after the etching process is completed.

Next, the base 1002 undergoes an oxidation process and a thin layer of a dielectric, such as SiO₂, is deposited on the surface of the base cavity 1004 and the vias 1010 (block 1106). Although the illustrated process 1100 includes depositing a thin layer of SiO₂, any type of dielectric may be applied.

The base cavity 1004 and the vias 1010 then undergo a metallization process that forms the feed-through metallization 1012 (block 1108). Conductive metal, such as Au or AuSn, is deposited on predetermined portions of the surface of the base cavity 1004 and the vias 1010. The feed-through metallization 1012 is formed by deposition of the conductive metal on the vias 1010. FIG. 16 illustrates the base 1002 and the feed-through metallization 1012 after the metallization process is completed.

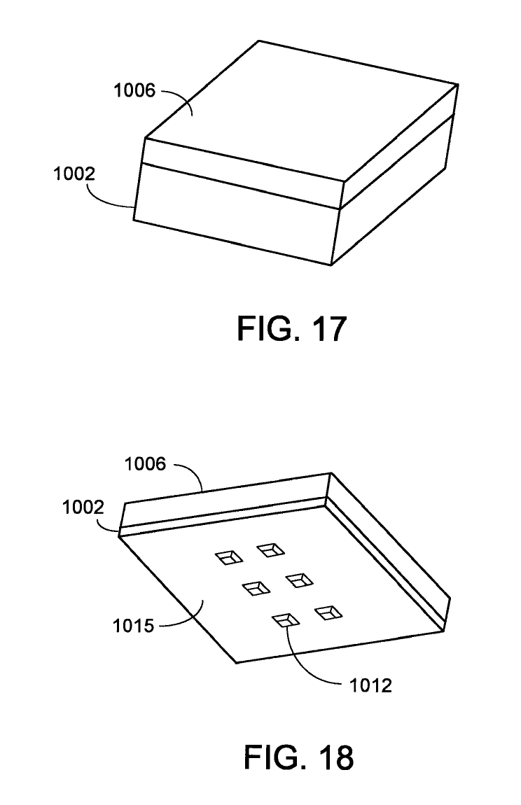

After the metallization process is completed, the lid 1006 then is positioned on the base 1002, such that the lid 1006 and the base 1002 are aligned and the device die is contained in the base cavity 1004, and is then sealed (block 1110). The lid 106 may be sealed to the base 102 using the sealing ring 1008 and a AuSn hermetic sealing process, adhesive bonding or some other type of sealing process. FIG. 17 is an illustration of the semiconductor package 1000 after the lid 1006 is sealed to the base 1002.

After the lid 1006 is sealed to the base 1002, the SMD side 1015 is processed to expose the feed-through metallization 1012 in the vias 1010 (block 1112). A mechanical grinding technique is used to reduce the thickness of the base 1002 and to form a particularly thin package. The flat wafer-to-wafer semiconductor package 1000 is supported by the lid 1006 for mechanical stability during the grinding process. The SMD side 1015 is thinned until there is approximately 10-20 μm separating the SMD side 1015 and the vias 1010. The SMD side 1015 is then dry etched to expose the feed-through metallization 1112 (block 1112). For example, the SMD side 1015 may be dry etched using an RIE process. As the base 1002 is made from silicon and the vias 1010 were metallized and protected by a dielectric layer, such as SiO₂ or SiₓN_{y}, the material of the base 1002 is removed at a faster rate than dielectric coating of the vias 1010. This difference in etching rate results in the vias 1010 and feed-throughs 1012 being exposed and protruding slightly beyond the SMD side 1015 of the base. FIG. 18 is an illustration of the SMD side 1015 of the base with the feed-through metallization 1012 exposed.

Next, the surface of the SMD side 1015 undergoes a BCB passivation and planarization process (block 1114). Although the illustrated process 1100 includes a BCB passivation and planarization process, other types of polymers having properties similar to BCB may be applied. The BCB passivates and planarizes the SMD side 1015. As a result of the BCB passivation and planarization process, the vias 1010 and feed-through metallization 1012 are buried by the BCB layer. Portions of the BCB layer covering the vias 1010 and the feed-through metallization 1012 are removed (i.e., the feed-through metallization 1012 is exposed) using a photolithographic technique followed by etching (block 1116).

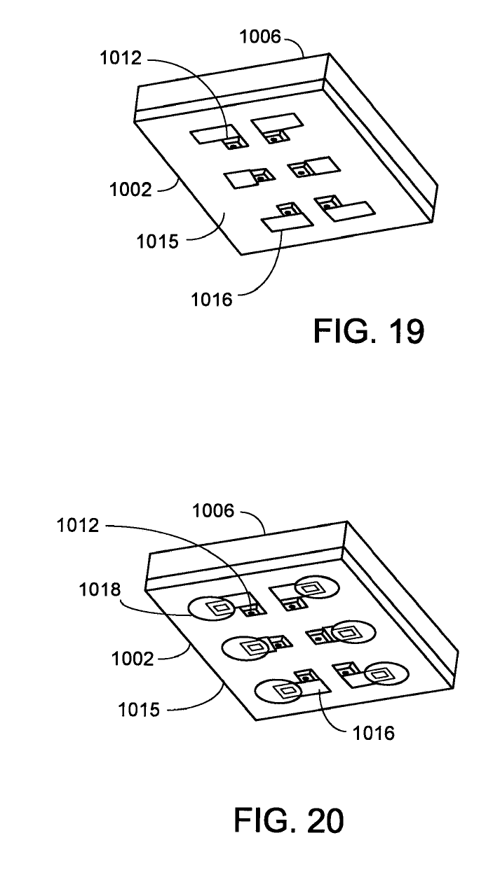

After the vias 1010 and feed-through metallization 1012 are exposed, the SMD side 1015 undergoes a metallization process to create the circuit routing 1016 on the SMD side 1015 (block 1118). The metallization process can be any type of metallization process. For example, the metallization process can be an electroplating process using a photoresist mold or a PVD process. The metallization process forms a layer of a conductive metal or alloy onto the surface of the SMD side 1015. The metal can be, but is not limited to, TiAu or TiCu. If a PVD process is used, the metal is etched to form the circuit routing 1016. FIG. 19 illustrates the SMD side 1015 after the circuit routing 1016 are etched.

The SMD side 1015 of the base 1002 undergoes a second BCB passivation process to planarize and insulate the circuit routing 1016 (block 1120). As a result of the second BCB passivation process, the vias 1010 and the circuit routing 1016 are buried by the BCB layer. The areas where the electrical contact pads 1018 will be formed (“the electrical contact pad area”) are then exposed with a photolithographic technique and an etching process, similar to the process described above in block 1116 (block 1121). The electrical contact pad area is then metallized to form the electrical contact pads 1018 using a metallization process such as electroplating or a PVD metal deposition process. FIG. 20 illustrates the SMD side 1015 after the electrical contact pads 1018 are formed.

After the electrical contact pads 1018 are formed, each individual wafer-to-wafer semiconductor package 1000 is formed (block 1124). The individual wafer-to-wafer semiconductor package 1000 can be formed by a dicing process. Other methods can be used to form the individual wafer-to-wafer semiconductor packages 1000.

In one implementation, the top of the lid 1006 (i.e., an externally-facing surface of the lid 1006) can be thinned after the electrical contact pads 1018 are formed to make the semiconductor package 1000 particularly thin. The top of the lid 1006 can be thinned using a mechanical grinding technique or an etching process. Alternatively, the top of the lid 1006 may be thinned at any step after the lid 1006 and the base 1002 are sealed (i.e., at any step after block 1110).

A number of implementations of the invention have been described. Nevertheless, various modifications may be made without departing from the spirit and scope of the invention. For example, in the chip-to-wafer semiconductor package 100, a sealing ring may be used to hermetically seal the lid 106 and the base 102. Accordingly, other implementations are within the scope of the following claims.

What is claimed is:

1. A wafer-level method of fabricating a semiconductor package, the method comprising:
etching a cavity into a first semiconductor wafer;
etching vias in a bottom of the cavity;
selectively metallizing portions of the cavity and sidewalls of the vias;
mounting an electrical circuit component in the cavity;
placing a second semiconductor wafer over the cavity-side of the first semiconductor wafer and sealing the first semiconductor wafer to the second semiconductor wafer;
thinning a backside of the first semiconductor wafer to expose metallization in the vias; and
depositing metal to form circuit routing paths on the backside of the first semiconductor wafer.

2. The method of claim 1 further comprising passivating and planarizing the backside of the first semiconductor wafer after the backside is thinned.

3. The method claim 1 further comprising passivating and planarizing the backside of the first semiconductor wafer after the circuit routing paths are formed.

4. The method of claim 2 wherein passivating and planarizing the backside of the first semiconductor wafer comprises using a polymide passivating and planarizing process.

5. The method of claim 4 wherein the polymide passivating and planarizing process is a benzoclyclobutene passivating and planarizing process.

6. The method of claim 2 further comprising exposing the metallization in the vias after passivating and planarizing the backside.

7. The method of claim 6 wherein exposing the metallization in the vias after passivating and planarizing the backside comprises using a photolithographic technique and an etching process.

8. The method of claim 2 wherein thinning the backside of the first semiconductor wafer comprises:
depositing a dielectric layer on the cavity and the sidewalls of the vias before the cavity and the sidewalls of the vias are metallized; and
thinning the backside such that the backside is thinned at a faster rate than the dielectric layer covering the vias to expose metallization in the vias.

9. The method of claim 2 including etching the second semiconductor wafer to form a cavity located such that when the first and second semiconductor wafers are sealed together, the cavity in the second wafer is opposite the cavity of the first semiconductor wafer.

10. The method of claim 9 wherein the electrical circuit component is housed in an area defined by the cavities.

11. The method of claim 9 wherein a combined depths of the cavities is at least as great as a height of the electrical circuit component.

12. The method of claim 9 wherein the depths of the cavities are substantially equal and the combined depths of the cavities are at least as great as the height of the electrical circuit component.

13. The method of claim 2 wherein etching the cavity into the first semiconductor wafer comprises etching the cavity to a depth at least as great as to the height of the electrical circuit component.

14. The method of claim 2 wherein thinning the backside of the first semiconductor wafer comprises a mechanical thinning process and an etching process.

15. The method of claim 2 further comprising thinning an externally-facing side of the second semiconductor wafer.

16. The method of claim 15 wherein thinning the externally-facing side of the second semiconductor wafer comprises a mechanical thinning process and an etching process.

17. The method of claim 1 further comprising:
aligning the second semiconductor wafer so the cavity of the first semiconductor wafer is positioned opposite a cavity of the second semiconductor wafer and the electrical circuit component is housed in an area defined by the cavities wherein a combined depths of the cavities is at least as great as to the height of the electrical circuit component;
hermetically sealing the first semiconductor wafer to the second semiconductor wafer;
thinning the backside of the first semiconductor wafer to expose metallization in the vias by mechanically thinning the backside of the first semiconductor wafer and then etching the backside of the first semiconductor wafer;
passivating and planarizing the backside of the first semiconductor wafer after the backside is etched; and
passivating and planarizing the backside of the first semiconductor wafer after the circuit routing paths are formed.

18. A wafer-level method of fabricating a semiconductor package, the method comprising:
etching a cavity into a first semiconductor wafer;
etching vias in a bottom of the cavity;
selectively metallizing portions of the cavity and sidewalls of the vias;
placing a second semiconductor wafer containing a device die over the cavity-side of the first semiconductor wafer and sealing the first semiconductor wafer to the second semiconductor wafer;
thinning a backside of the first semiconductor wafer to expose metallization in the vias; and
depositing metal to form circuit routing paths on the backside of the first semiconductor wafer.

19. The method of claim 18 further comprising passivating and planarizing the backside of the first semiconductor wafer after the backside is thinned.

20. The method of claim 18 further comprising passivating and planarizing the backside of the first semiconductor wafer after the circuit routing paths are formed.

21. The method of claim 19 wherein placing the second semiconductor wafer over the cavity-side of the first semiconductor wafer comprises aligning the second semiconductor wafer so the device die is positioned over the cavity.

22. The method of claim 19 wherein etching the cavity comprises etching the cavity to a depth at least as great as a height of the device die.

23. The method of claim 19 wherein thinning the backside of the first semiconductor wafer comprises a mechanical thinning process and an etching process.

24. The method of claim 19 wherein thinning the backside of the first semiconductor wafer comprises:
depositing a dielectric layer on the cavity and the sidewalls of the vias before the cavity and sidewalls of the vias are metallized; and
thinning the backside such that the backside is thinned at a faster rate than the vias covered by the dielectric layer to expose metallization in the vias.

25. The method of claim 19 further comprising exposing the metallization in the vias after passivating and planarizing the backside.

26. The method of claim 25 wherein exposing the metallization in the vias after passivating and planarizing the backside comprises using a photolithographic technique and an etching process.

27. The method of claim 19 further comprising thinning an externally-facing side of the second semiconductor wafer.

28. The method of claim 27 wherein thinning the externally-facing side of the second semiconductor wafer comprises a mechanical thinning process and an etching process.
